(19) United States
(12) Patent Application Publication
(10) Pub. No.: US 2019/0123510 A1
(43) Pub. Date: Apr. 25, 2019

(54) SUPPORT RACK FOR A LASER MACHINE

(71) Applicant: Mega 1 Company Limited, New Taipei City (TW)

(72) Inventors: YONG-WEI GAO, NEW TAIPEI CITY (TW); RUEI-TIAN LI, NEW TAIPEI CITY (TW)

(21) Appl. No.: 15/788,436

(22) Filed: Oct. 19, 2017

(51) Int. Cl. H01S 5/022; H01S 5/40; H01S 5/024

(52) U.S. Cl. CPC H01S 5/02256; H01S 5/02469; H01S 5/4093

(57) ABSTRACT

A support rack for a laser machine, that includes: a metal shell having a plurality of installation holes. A notch is provided on each of the installation holes, so that when the laser diode is place in the installation hole, the surface of the hole tends to press tightly against the laser diodes. As such, the heat generated by the laser diodes can be dissipated readily out of the metal shell, in achieving reduction of temperature of the laser machine.

### BACKGROUND OF THE INVENTION

### Field of the Invention

The present invention relates to a support rack for a laser machine, and in particular to a support rack for a laser machine, for which laser diodes can be inserted and held in the shell of the laser machine.

### The Prior Arts

For the conventional laser machine, a plurality of laser diodes are fixed onto the laser machine made of metal, and through a plurality of reflection mirrors, the laser lights emitted by the three types of laser diodes RGB (Red, Green, Blue) are reflected to a screening mirror. Then, the laser lights are emitted out of the laser machine through a light output port.

However, the laser diodes are glued and fixed on the laser machine, such that gaps exist between them, and that could accumulate heat generated by the laser diodes, thus leading to poor heat dissipation.

In addition, the installation holes on the laser machine for installing the laser diodes are of a fixed size, such that when the size of the laser diodes is greater than the normal and standard size, laser machine of special specifications has to be used.

Therefore, presently, the design and performance of the laser machine is not quite satisfactory, and it leaves much room for improvement.

### SUMMARY OF THE INVENTION

In view of the problems and drawbacks of the prior art, the present invention provides a support rack for a laser machine to overcome the shortcomings or the prior art.

The present invention provides a support rack for a laser machine, that includes: a metal shell having a plurality of installation holes. When the laser diodes are installed in the installation holes respectively, the surface of the hole tends to press tightly against the laser diode, so that the heat generated by the laser diodes can be dissipated readily out of the metal shell, in achieving reduction of temperature of the laser machine.

In order to achieve the objective mentioned above, the technical characteristic of the present invention is that, a notch is provided on the installation hole. As such, in case the size of the laser diode is greater than the normal and standard size, the size of the installation hole can be expanded and enlarged slightly, to accommodate the laser diode, while the surface of the installation hole pressing tightly against the laser diode, to raise the heat dissipation efficiency.

Further scope of the applicability of the present invention will become apparent from the detailed descriptions given hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from the detailed descriptions.

### BRIEF DESCRIPTION OF THE DRAWINGS

The related drawings in connection with the detailed descriptions of the present invention to be made later are described briefly as follows, in which:

FIG. 1 is a perspective view of a support rack for a laser machine according to the present invention; and

FIG. 2 is a partial enlarged view of a support rack for a laser machine of FIG. 1 according to the present invention.

### DETAILED DESCRIPTION OF THE PREFERRED EMBODIMENT

The purpose, construction, features, functions and advantages of the present invention can be appreciated and understood more thoroughly through the following detailed descriptions with reference to the attached drawings.

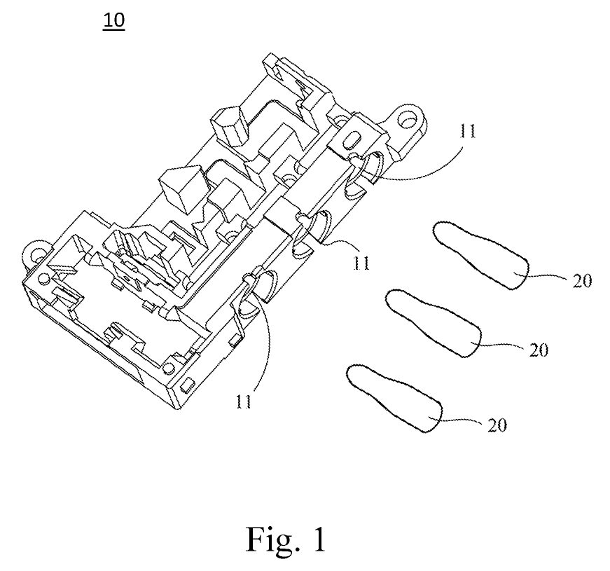

Refer to FIG. 1 for a perspective view of a support rack for a laser machine according to the present invention. As shown in FIG. 1, the support rack for a laser machine includes: a shell 10 made of metal. On a side of the shell 10 is provided with a plurality of installation holes 11, to receive a laser diode 20 respectively. The diameter of the installation holes 11 is slightly less than that of the laser diode 20. The support rack for a laser machine makes use of the fast lighting feature of the laser diode 20, so that when three light sources of RGB emit lights alternatively at high speed, it could replace the single-piece projection system color-wheel light splitter in application.

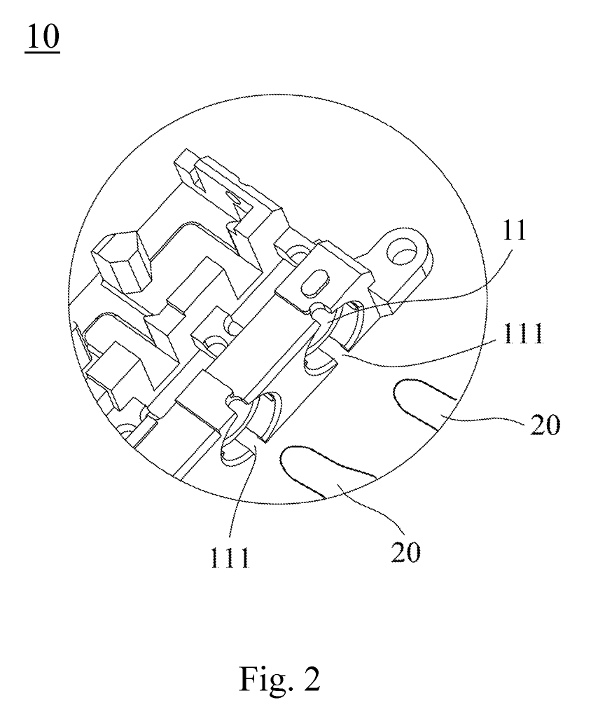

Then, refer to FIG. 2 for partial enlarged view of a support rack for a laser machine of FIG. 1 according to the present invention. As shown in FIG. 2, on each laser diode 20 is provided with a notch 111. Since the shell 10 and the installation holes 11 are made of metal having inherent resilience, such that when the laser diode 20 is inserted into the installation holes 11, due to the resilience of metal, the installation holes 11 is made to expand slightly from the notch 111 by the laser diode 20, so that the surface of the installation hole 11 tends to press tightly against the surface of the laser diode 20. As such, the heat generated by the laser diode 20 can be dissipated through the metal of the shell 10, in achieving raising heat dissipation efficiency.

Refer again to FIGS. 1 and 2, in case the size of the laser diode 20 is greater than the normal size, when installing the laser diode 20 onto the shell 10, the installation hole 11 can be expanded and enlarged slightly through the notch 111, to receive the laser diode 20.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A support rack for a laser machine, comprising:
a shell made of metal, with a side of the shell provided with a plurality of installation holes, to receive respectively a laser diode, and is characterized in that, each of the installation holes is provided with a notch, in case a size of the laser diode is greater than a normal size, the installation hole is expanded to receive the laser diode through the notch.
